(19) United States
(12) Patent Application Publication
(10) Pub. No.: US 2024/0112878 A1
(43) Pub. Date: Apr. 4, 2024

(54) CHARGED PARTICLE MICROSCOPE HAVING VACUUM IN SPECIMEN CHAMBER

(71) Applicant: FEI COMPANY, Hillsboro, OR (US)

(72) Inventors: Pleun Dona, Hillsboro, OR (US); Johannes A.H.W.G. Persoon, Hillsboro, OR (US); Hugo Cornelis Van Leeuwen, Hillsboro, OR (US); Peter Tiemeijer, Hillsboro, OR (US)

(21) Appl. No.: 17/957,171

(22) Filed: Sep. 30, 2022

(51) Int. Cl. H01J 37/18; H01J 37/141; H01J 37/20

(52) U.S. Cl. CPC H01J 37/18; H01J 37/141; H01J 37/20

(57) ABSTRACT

A charged particle microscope for imaging a specimen. The charged particle microscope includes a specimen holder movable into an imaging position intersecting an optical axis, a specimen chamber configured to receive the specimen holder in the imaging position, and a sorption pump disposed in the specimen chamber and configured to lower a pressure in the specimen chamber.

### BACKGROUND

The present disclosure relates to a charged particle microscope, such as a transmission electron microscope (TEM), a scanning transmission electron microscope (STEM), a scanning electron microscope (SEM), and/or a focused ion beam (FIB) microscope, etc. The microscope typically has a specimen chamber in which a specimen-to-be-imaged is disposed during an imaging operation. Charged particles, such as electrons, are directed at the specimen through a vacuum in the specimen chamber to create a high-resolution magnified image of the specimen. Pressure in the specimen chamber must be reduced well below atmospheric pressure to create the vacuum. Typically, the specimen chamber is pumped to move gas inside the specimen chamber to a location outside of the specimen chamber through a port.

### SUMMARY

The final pressure that can be achieved in the specimen chamber is proportional to the effective pumping speed. That is, the higher the effective pumping speed, the lower the final pressure that can be achieved. However, endlessly enlarging a pump's capacity does not proportionally increase the effective pumping speed (as will be described in the detailed description below). Enlarging the pump's capacity has diminishing returns due to the port diameter being physically constrained to size limits within the microscope, thereby limiting the effective pumping speed. As such, an ultra-high vacuum (UHV) may not be achievable by enlarging pump capacity without the microscope being unable to operate as intended.

In one implementation, the disclosure provides a charged particle microscope for imaging a specimen. The charged particle microscope includes a specimen holder movable into an imaging position intersecting an optical axis, a specimen chamber configured to receive the specimen holder in the imaging position, and a sorption pump disposed in the specimen chamber and configured to lower a pressure in the specimen chamber.

In another implementation, the disclosure provides a magnetic assembly for a charged particle microscope defining an optical axis. The magnetic assembly includes at least one magnetic yoke configured to concentrate magnetic field lines for guiding a charged particle beam along the optical axis. The magnetic yoke at least partially defines a specimen chamber, the magnetic yoke defining at least one pumping port configured to fluidly couple the specimen chamber to an external pump for lowering a pressure in the specimen chamber. The magnetic assembly also includes a sorption pump disposed in the specimen chamber and configured to further lower the pressure in the specimen chamber.

In yet another implementation, the disclosure provides a method of achieving a vacuum in a charged particle microscope specimen chamber. The method includes providing the specimen chamber configured to receive a specimen holder in an imaging position intersecting a charged particle optical axis, activating an external vacuum pump to create an initial vacuum condition in the specimen chamber, and activating a sorption pump to further lower a pressure in the specimen chamber.

Other aspects of the disclosure will become apparent by consideration of the detailed description and accompanying drawings.

### BRIEF DESCRIPTION OF THE DRAWINGS

FIG. 1 schematically illustrates a longitudinal cross-sectional elevation view of a charged particle microscope in accordance with an implementation of the present disclosure.

FIG. 2 is an enlarged and more detailed view of a magnetic assembly defining a specimen chamber of the charged particle microscope shown in FIG. 1.

FIG. 3 is a cross-sectional top view of the magnetic assembly taken through line 3-3 in FIG. 2.

FIG. 4 is a method flow chart in accordance with the present disclosure.

### DETAILED DESCRIPTION

Before any implementations of the disclosure are explained in detail, it is to be understood that the disclosure is not limited in its application to the details of construction and the arrangement of components set forth in the following description or illustrated in the following drawings. The disclosure is capable of other implementations and of being practiced or of being carried out in various ways.

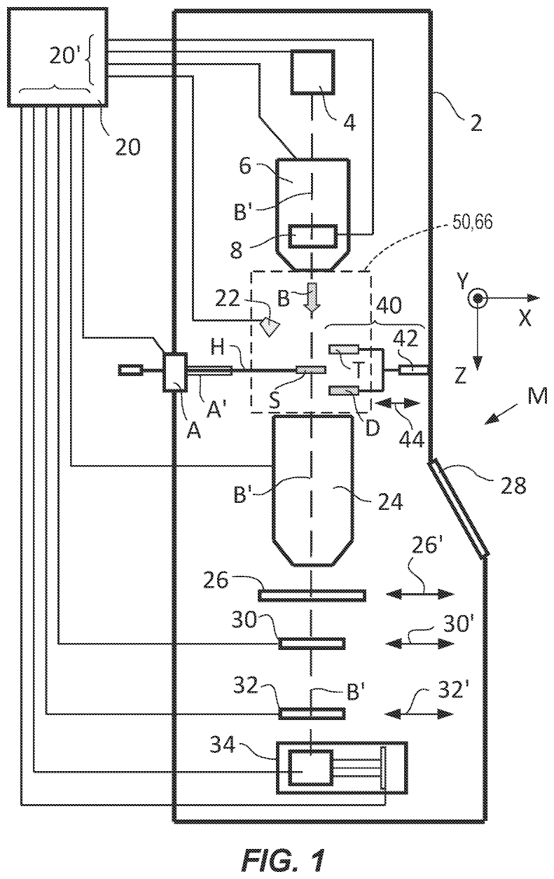

FIG. 1 is a highly schematic depiction of an implementation of a charged particle microscope M in which the present invention can be implemented; more specifically, it shows an implementation of a transmission-type microscope M, which, in this case, is a TEM/STEM, but may include any other type of electron-based microscope, or an ion-based microscope, a proton-based microscope, or any other type of charged particle microscope. In FIG. 1, within a vacuum enclosure 2, an electron source 4 produces a beam B of electrons that propagates along an optical axis B′ (which may be generally referred to herein as a charged particle beam axis), and traverses an optical illuminator 6, serving to direct/focus the electrons (or other charged particles) onto a chosen part of a specimen S (which may, for example, be (locally) thinned/planarized). Also depicted is a deflector 8, which (inter alia) can be used to effect scanning motion of the beam B. Although a transmission-type electron microscope M is described in detail herein, the disclosure applies to any type of charged particle microscope M. The charged particle microscope M may include other types of charged particle microscopes, such as a SEM, a FIB, etc. Accordingly, the beam B may be an ion beam, a proton beam, or any other type of charged particle.

The specimen S is held on a specimen holder H that can be positioned in multiple degrees of freedom by a positioning device/stage A, which moves a cradle A′ into which the specimen holder H is (removably) affixed; for example, the specimen holder H may comprise a finger that can be moved (inter alia) in the XY plane (see the depicted Cartesian coordinate system; typically, motion parallel to Z and tilt about X/Y will also be possible). Such movement allows different parts of the specimen S to be illuminated/imaged/inspected by the electron beam B traveling along the optical axis B′ (in the Z direction) (and/or allows scanning motion to be performed, as an alternative to beam scanning). If desired, an optional cooling device (not depicted) can be brought into intimate thermal contact with the specimen holder H, so as to maintain it (and the specimen S thereupon) at cryogenic temperatures, for example.

The electron beam B will interact with the specimen S in such a manner as to cause various types of “stimulated” radiation to emanate from the specimen S, including (for example) secondary electrons, backscattered electrons, X-rays and optical radiation (cathodoluminescence). If desired, one or more of these radiation types can be detected with the aid of analysis device 22, which might be a combined scintillator/photomultiplier or EDX (Energy-Dispersive X-Ray Spectroscopy) module, for instance; in such a case, an image could be constructed using basically the same principle as in a scanning electron microscope (SEM). However, alternatively or supplementally, one can study electrons that traverse (pass through) the specimen S, exit/emanate from it and continue to propagate (substantially, though generally with some deflection/scattering) along the optical axis B′. Such a transmitted electron flux enters an imaging system (projection lens) 24, which will generally comprise a variety of electrostatic/magnetic lenses, deflectors, correctors (such as stigmators), etc. In normal (non-scanning) TEM mode, this imaging system 24 can focus the transmitted electron flux onto a fluorescent screen 26, which, if desired, can be retracted/withdrawn (as schematically indicated by arrows 26′) so as to get it out of the way of the optical axis B′. An image (or diffractogram) of (part of) the specimen S will be formed by imaging system 24 on screen 26, and this may be viewed through viewing port 28 located in a suitable part of a wall of enclosure 2. The retraction mechanism for screen 26 may, for example, be mechanical and/or electrical in nature, and is not depicted here.

As an alternative to viewing an image on screen 26, one can instead make use of the fact that the depth of focus of the electron flux leaving imaging system 24 is generally quite large (e.g. of the order of 1 meter). Consequently, various other types of analysis/sensing devices can be used downstream of screen 26, such as a TEM camera 30, a STEM camera 32, and/or a spectroscopic apparatus 34.

At the TEM camera 30, the electron flux can form a static image (or diffractogram) that can be processed by a controller 20 (which may include a processor, a memory, and inputs and outputs) and displayed on a display device (not depicted), such as a flat panel display, for example. When not required, the TEM camera 30 can be retracted/withdrawn (as schematically indicated by arrows 30′) so as to get it out of the way of the optical axis B′.

An output from the STEM camera 32 can be recorded as a function of (X,Y) scanning position of the beam B on the specimen S, and an image can be constructed that is a “map” of output from the STEM camera 32 as a function of X,Y. The STEM camera 32 can comprise a single pixel with a diameter (of e.g., 20 mm, or any other suitable diameter), as opposed to the matrix of pixels characteristically present in the TEM camera 30. Moreover, the STEM camera 32 will generally have a much higher acquisition rate (e.g., 10⁶ points per second) than the TEM camera 30 (e.g., 10² images per second). Once again, when not required, the STEM camera 32 can be retracted/withdrawn (as schematically indicated by arrows 32′) so as to get it out of the way of the optical axis B′ (although such retraction would not be a necessity in the case of the STEM camera 32 being embodied as a donut-shaped annular dark field camera, for example; in such a camera, a central hole would allow flux passage when the camera was not in use).

As an alternative (or in addition) to imaging using the TEM camera 30 and the STEM camera 32, one can also invoke the spectroscopic apparatus 34, which could be an electron energy loss spectroscopy (EELS) module, for example.

It should be noted that the order/location of items 30, 32 and 34 is not strict, and many possible variations are conceivable. For example, the spectroscopic apparatus 34 can also be integrated into the imaging system 24.

Note that the controller 20 is connected to various illustrated components via control lines (buses) 20′. This controller 20 can provide a variety of functions, such as synchronizing actions, providing setpoints, processing signals, performing calculations, and displaying messages/information on a display device (not depicted). Needless to say, the (schematically depicted) controller 20 may be (partially) inside or outside the enclosure 2, and may have a unitary or composite structure, as desired.

The skilled artisan will understand that the interior of the enclosure 2 does not have to be kept at a strict vacuum; for example, in a so-called “Environmental TEM/STEM”, a background atmosphere of a given gas is deliberately introduced/maintained within the enclosure 2. The skilled artisan will also understand that, in practice, it may be advantageous to confine the volume of enclosure 2 so that, where possible, it essentially hugs the optical axis B′, taking the form of a small tube (e.g., of the order of 1 cm in diameter) through which the employed electron beam B passes, but widening out to accommodate structures such as the source 4, the specimen holder H, the screen 26, the TEM camera 30, the STEM camera 32, the spectroscopic apparatus 34, etc.

The microscope M may include a retractable X-ray CT module 40, which can be advanced/withdrawn with the aid of positioning system 42 so as to place it on/remove it from the path of the beam B (see arrow 44). In the particular configuration illustrated here, the module 40 comprises a fork-like frame on which are mounted: a target T and an X-ray detector D. The target T is disposed above the plane of the specimen S. The X-ray detector D is disposed below the plane of the specimen S.

The microscope M also includes a magnetic assembly 50 defining a specimen chamber 52 (which may also be referred to herein as a vacuum chamber 52). The magnetic assembly 50 is disposed between the optical illuminator 6 and the imaging system 24 in the direction of the optical axis B′. (The upper end of the magnetic assembly 50 is the lower end of the optical illuminator 6 and the lower end of the magnetic assembly 50 is the beginning of the imaging system 24.) The specimen holder H is received in the specimen chamber 52 in an imaging position (illustrated in FIG. 1) intersecting the optical axis B′. The imaging position is the position in which the specimen S is imaged. The electron beam B intersects the specimen S in the imaging position. The optical axis B′ passes through the magnetic assembly 50. The optical axis B′ may be aligned with a center, or near the center, of the magnetic assembly 50.

In some examples, the magnetic assembly 50 may overlap with either or both of the illuminator 6 and the imaging system 24. For example, one or more lenses of the illuminator may be positioned in the magnetic assembly 50 for directing the charged particle beam towards the specimen.

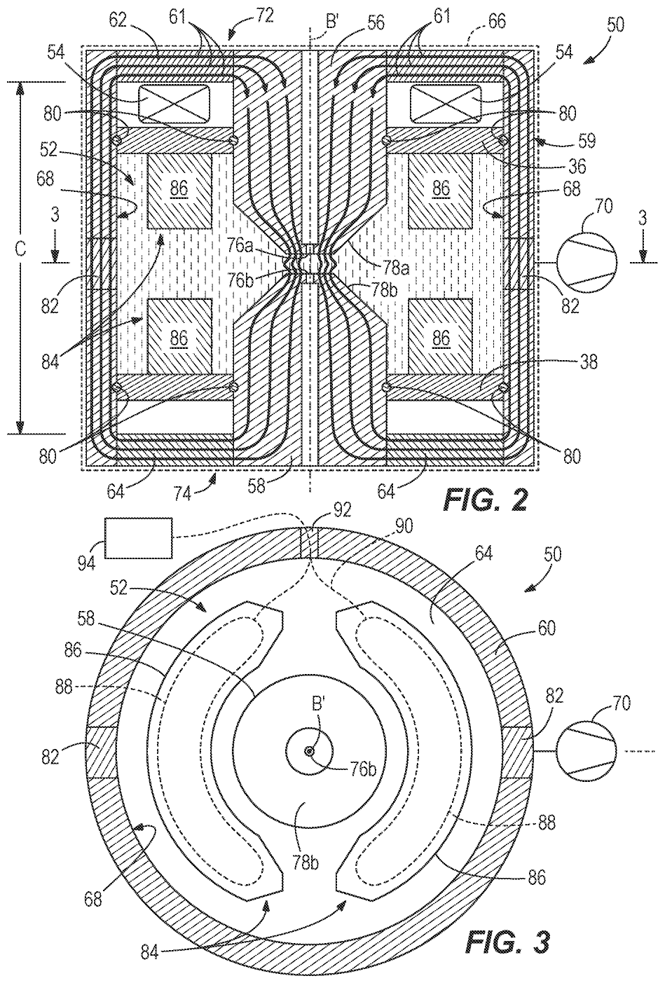

As best illustrated in FIGS. 2-3, the magnetic assembly 50 includes any number of pieces of magnetic material arranged to shape the magnetic field and guide flux, said piece(s) of magnetic material forming a magnetic yoke 59. For example, as illustrated, the magnetic yoke 59 includes a first pole piece 56, a second pole piece 58, a yoke housing 60, a first yoke plate 62, and a second yoke plate 64, each of which include a magnetic material of relatively high permeability (compared to its surroundings, such as air) that concentrates magnetic field lines 61 into one or more magnetic circuits (closed loops). The magnetic field lines 61 guide the electron beam B (or other charged particle beam) along the optical axis B′ at the specimen S. For example, the magnetic material may include iron, an alloy of nickel-iron, an alloy of cobalt-iron, or any combination thereof. Other magnetic materials may also be employed. The choice of material depends mainly on its maximum magnetic saturation and on its magnetic remanence. Different pieces of the magnetic yoke 59 may be formed from different magnetic materials or the same magnetic materials, as desired. The pieces of the magnetic yoke 59 may be integrated (in any combination) into fewer monolithic parts. For example, the yoke housing 60 may be integrated (e.g., formed as one piece) with one or both of the first yoke plate 62 and the second yoke plate 64; the first pole piece 56 and/or the second pole piece 58 may be integrated with one or both of the first yoke plate 62 and the second yoke plate 64; etc. Any one or more of the pieces of the magnetic yoke 59 may also be separated (in any combination) into more monolithic parts. For example, any of said pieces of the magnetic yoke 59 may be formed from two separate pieces, or more.

The magnetic assembly 50 also includes at least one coil 54. One coil 54 is illustrated in FIG. 2, however any number of coils 54 may be employed, such as two, three, four, or more. In the charged particle microscope M, the charged particles are focused by electric fields or magnetic fields. In the illustrated implementation, a magnetic field is employed. The coil 54 carries windings of wire positioned rotationally symmetrically around the optical axis B′ of the microscope M. The coil 54 is excited by a current, e.g., of several Amperes. Water cooling may be employed. While excited, the coil 54 creates a strong magnetic field on the optical axis B′ of the microscope M in the axial direction (that is, coaxial with or parallel to the optical axis B′). Since the magnetic field is divergence-free, it inherently has components in the radial direction (that is, perpendicular to the optical axis B′). These radial components grow linearly with the distance to the optical axis B′, and their net effect is a deflection of the charged particles towards the optical axis B′ that scales linearly with the distance of these particles to the optical axis B′. Hence, such a magnetic field acts as a round focusing lens. The focusing strength of a magnetic lens scales with the square of the axial magnetic field and with the length of the axial magnetic field (as measured along the optical axis B′). Therefore, in order to obtain a magnetic lens (i.e., to create lens action), the magnetic field is concentrated in a small region on the optical axis B′ by the magnetic yoke 59 around the coil 54 to guide and focus its magnetic flux to the imaging position on the optical axis B′. The imaging position may only be a few millimeters in length.

Thus, the magnetic assembly 50 at least partially contributes to providing desirable magnetic conditions at the specimen S for imaging (and thus at the specimen holder H in the imaging position), sometimes in combination with other components outside of the magnetic assembly 50. The concentrated magnetic field lines 61 in the magnetic material (and particularly the outermost of the concentrated magnetic field lines 61) define a specimen chamber volume 66 in which the specimen holder H is disposed in the imaging position.

The magnetic assembly 50 may include one or more inner plates positioned at the top and/or bottom of the specimen chamber 52. The magnetic assembly 50 may include inner walls (not shown in FIG. 2) surrounding the specimen chamber 52, separating the specimen chamber from the yoke housing 60. The specimen chamber 52 may thus be partially defined by the one or more inner plates and the inner walls. The inner plates and the inner walls may provide sealing of the specimen chamber from the external environment. The inner plates and the inner walls may be formed of a non-magnetic material. In some examples, the inner walls are omitted.

As an example, FIG. 2 shows a first inner plate 36 and a second inner plate 38. The first inner plate 36 separates the coil 54 from the vacuum condition in the specimen chamber 52, e.g., by one or more seals 80 between the first inner plate 36 and the yoke housing 60. The first inner plate 36 and the second inner plate 38 may be formed of a non-magnetic material, if desired. The second inner plate 38 may be omitted, if desired. The yoke housing 60 defines walls 68 of the specimen chamber 52 that, at least partially, enclose and maintain a vacuum condition in the specimen chamber 52. The vacuum condition in the specimen chamber 52 is independent from the vacuum in the enclosure 2. As discussed above, the interior of the enclosure 2 does not have to be kept at a strict vacuum. In contrast, the vacuum levels in the specimen chamber 52 are of more importance and will be described in greater detail below. For creating the vacuum in the specimen chamber 52, at least in part, the microscope M also includes a vacuum pump 70 disposed outside of (external to) the specimen chamber 52. The vacuum pump 70 may include any pump generally configured to move a fluid, such as air and/or other gas, from one location to another. For example, the vacuum pump 70 may include a turbo molecular pump, and/or a mechanical pump having moving parts. The turbo molecular pump may include one or more pumps that operate without moving parts on the principles of chemisorption and/or physisorption, such as a getter pump, an ion pump, or the like, disposed outside of the specimen chamber 52. The vacuum pump 70 removes fluid from the specimen chamber 52 to lower a pressure in the specimen chamber (e.g., to create a vacuum). For example, the fluid may be pumped to the atmosphere. Vacuum conditions in the specimen chamber 52 will be described in greater detail below.

Returning to the structure of the magnetic yoke 59, the yoke housing 60 has a generally tubular (e.g., cylindrical) configuration with the optical axis B′ passing therethrough from a first open end 72 to a second open end 74. The first yoke plate 62 is disposed in the first open end 72 of the yoke housing 60 and the second yoke plate 64 is disposed in the second open end 74 of the yoke housing 60. Each of the first yoke plate 62 and the second yoke plate 64 is generally planar (e.g., a disc, such as a circular disc or any other suitable shape) and disposed generally perpendicular to the optical axis B′. The first pole piece 56 and the second pole piece 58 each include an aperture 76a, 76b aligned with the optical axis B′, and each 56, 58 extends generally from the respective first or second yoke plate 62, 64 towards the specimen holder H in the imaging position. Each of the first pole piece 56 and the second pole piece 58 has a tapered portion 78a, 78b that generally tapers radially inwards towards the optical axis B′ with each tapered portion 78a, 78b closest to the specimen holder H in the imaging position. Each of the yoke housing 60, the first and second yoke plates 62, 64, and the first and second pole pieces 56, 58 serves to concentrate the magnetic field lines 61 and guide the magnetic field lines 61 in one or more circuits; however, it should be appreciated that the magnetic yoke 59 may include any number of pieces including the magnetic material, said pieces having any desired shape and configuration to create a desired effect on the charged particles for imaging.

The yoke housing 60 and/or the first and second inner plates 36, 38 collectively define the walls 68 of the specimen chamber 52 that are at least partially responsible for holding the vacuum condition in the specimen chamber 52, though it should be appreciated that other shapes and configurations of the walls 68 may also provide the same function, and that other parts may also contribute to holding the vacuum condition (e.g., seals 80, valves, etc.). The apertures 76a, 76b may also define a boundary of the vacuum condition within the specimen chamber 52.

The magnetic yoke 59 defines an inner magnetic yoke height C (FIG. 2) defined in a direction parallel to the optical axis B′ (e.g., see also the Z-direction in FIG. 1) between the first yoke plate 62 and the second yoke plate 64. The inner magnetic yoke height C is at least 5 cm. In some implementations, the inner magnetic yoke height C is at least 8 cm. In some implementations, the inner magnetic yoke height C is at least 10 cm. In some implementations, the inner magnetic yoke height C is at least 15 cm. In some implementations, the inner magnetic yoke height C is from 5 cm to 40 cm. In some implementations, the inner magnetic yoke height C is from 15 cm to 35 cm. In some implementations, the inner magnetic yoke height C is from 25 cm to 35 cm.

The magnetic yoke 59 provides access to the specimen chamber 52 for various application purposes by means of one or more ports 82 (e.g., holes) in the magnetic material. These ports 82 cannot be made too large, as the magnetic material will start to saturate when the material between the ports 82 becomes too shallow. As a consequence, the pumping speed that the vacuum pump 70 can effectively achieve at the specimen chamber 52 will be limited by the port diameter; enlarging the capacity of the vacuum pump 70 will not help beyond a certain point. (For example, for a known TEM with a port diameter of 40 mm and an external ion getter pump (IGP) pumping at 40l/s, the effective pumping speed is roughly 10l/s; and for another known TEM with a 70 mm port and an external IGP pumping at 150l/s, the effective pumping speed is about 30l/s.)

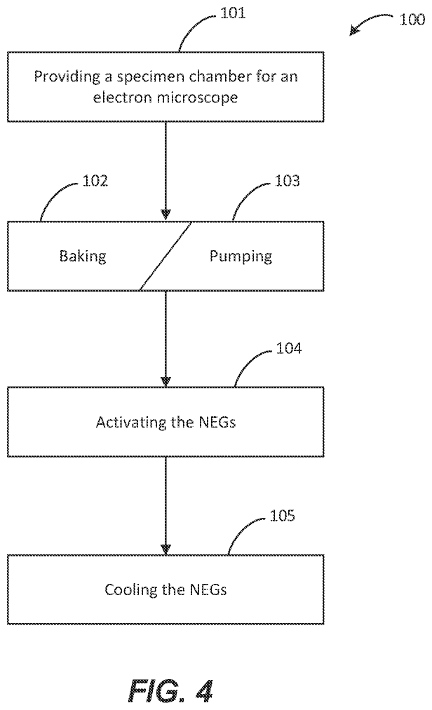

The final pressure P that can be achieved in a vacuum chamber (e.g., in the specimen chamber 52) is roughly governed by the simple formula P=Q/Sₑ, where P is the final pressure, Q is the outgassing of the total surface area, and Sₑ is the effective pumping speed at the chamber (e.g., the specimen chamber 52) as discussed above. In order to achieve ultra-high vacuum (UHV) in the specimen chamber 52, which is two orders of magnitude better vacuum than currently achieved in a TEM, the outgassing Q may be reduced and/or the effective pumping speed Sₑ may be increased. Some outgassing reduction (reduction of Q) may be achieved by baking (e.g., heating the specimen chamber to 150° C. for multiple days). (Baking is further described below with respect to step 103 of the method 100 shown in FIG. 4.) Sufficiently increasing the effective pumping speed Sₑ inside the specimen chamber to achieve UHV cannot be achieved from endlessly increasing external pumping speeds and port diameters because of the physical constraints discussed above.

The effective pumping speed Sₑ is further increased by pumping directly on the specimen chamber 52 by disposing one or more internal vacuum pumps 84 with high capacity in the specimen chamber 52 itself. Direct pumping does not move fluid through the ports 82 (though direct pumping may be employed in addition to external pumping through the ports 82). Rather, an internal vacuum pump 84 employing the principle of sorption (i.e., a sorption pump 84 in this example) is disposed in the specimen chamber 52 to avoid the pumping speed limitations associated with having to pass molecules through the pumping port(s) 82. The entirety of the internal vacuum pump is within the specimen chamber 52. The inner magnetic yoke height C provides adequate volume (specimen chamber volume 66) in the specimen chamber 52 to include the internal vacuum pump 84, as well as the at least one coil 54. Due to the magnetic nature of the specimen chamber (e.g., because of the magnetic material concentrating magnetic field lines 61 around and through the specimen chamber in which the internal vacuum pump 84 is to be disposed), there are many challenges in selecting the internal vacuum pump 84 for this application. Magnetic fields interfere with some types of sorption pumps (or vice-versa). For example, pumps having their own magnetic fields may be interfered with by the magnetic assembly 50 or may interfere with the magnetic assembly 50. However, the internal vacuum pump 84 may include any relatively non-magnetic sorption pump, such as a non-evaporable getter (NEG) pump, for example, which is not magnetic. The internal vacuum pump 84 is relatively non-magnetic when it has little or no effect on the magnetic field at the region of the specimen. Any type of NEG material may be employed. As one example, a NEG material operating on the principle of metallic surface sorption may be employed; more specifically, a sintered porous getter alloy (such as ZAO®) may be employed. Other types of NEG materials may also be employed. Other relatively non-magnetic sorption pumps may be employed.

The internal vacuum pump 84 may have any shape or form that fits in the specimen chamber 52 without interfering with the specimen S (and insertion thereof) or any other probes, etc., that may be inserted into the specimen chamber 52. The internal vacuum pump 84 may include one or more NEGs shaped and/or arranged within the specimen chamber in any suitable fashion. In the illustrated implementation, the internal vacuum pump 84 includes four NEG units 86, each NEG unit 86 including any number of NEG pumps (e.g., a stack of four NEG pumps may be employed in each NEG unit 86 in the illustrated implementation, though the exact number is not depicted in the drawings). Any number of NEG units 86 and any number of NEG pumps in a NEG unit 86 may be employed. Each NEG unit 86 may have a generally arcuate shape (as shown in FIG. 3) in order to fit within the limited space of the specimen chamber 52, e.g., around the first and second pole pieces 56, 58. In some implementations, each NEG unit 86 may be non-arcuate (e.g., rectangular or another shape) and may be arranged in series with other NEG units 86, the series of NEG units 86 generally forming an arcuate shape, or any other shape that fits within the physical constraints of the magnetic yoke 59. For example, one or more NEG units 86 may be disposed in a generally annular arrangement around the first and second pole pieces 56, 58, i.e., around the optical axis B′. However, the internal vacuum pump 84 may be manufactured into any suitable shape and dimension to fit the space and may be disposed in the specimen chamber 52 as one piece or in multiple pieces. Thus, the internal vacuum pump 84 is disposed in the specimen chamber volume 66. Typically, there is not enough room in the specimen chamber for NEGs; as such, the inner magnetic yoke height C is elongated (e.g., having the dimensions described above) in order to increase the specimen chamber volume 66 to accommodate the internal vacuum pump 84. In other implementations, the specimen chamber volume 66 may be increased in other ways, e.g., by elongating other dimensions of the magnetic assembly 50, reducing or eliminating parts (e.g., reducing or eliminating a coil 54), or making parts smaller, thinner, etc.

Generally, the internal vacuum pump 84 is disposed between the first and second yoke plates 62, 64 in the direction of the optical axis B′, and the internal vacuum pump 84 is disposed between the yoke housing 60 and the first and second pole pieces 56, 58 in the radial direction of the optical axis B′. More specifically, the internal vacuum pump 84 is disposed between the first and second inner plates 36, 38 in the direction of the optical axis B′.

The internal vacuum pump 84 is passive and requires no electricity during operation; however, the internal vacuum pump 84 may be activated, e.g., by temperature (e.g., heated to at least 400 degrees Celsius, or any other suitable temperature in other implementations) in order to operate. The internal vacuum pump 84 may be activated during the initial manufacture/setup of the microscope M and also may thereafter be activated after each column vent. One or more heaters 88 (such as resistive heaters or any other suitable type of heater) is integrated into each NEG unit 86 of the internal vacuum pump 84, in thermal contact with the NEGs, for activating the NEGs. At least one electrical passthrough 90 is configured to power the heater(s) 88 and is disposed at least partially in the specimen chamber 52 to electrically connect to the NEG unit 86 of the internal vacuum pump 84. The electrical passthrough 90 passes through an electrical port 92 in the magnetic assembly 50, e.g., in the yoke housing 60 in the illustrated implementation, but may pass through other parts of the magnetic assembly 50 in other implementations. A power source 94 (illustrated schematically in FIG. 3), external to the magnetic assembly 50, provides power to activate the internal vacuum pump 84 by way of the electrical passthrough 90.

The internal vacuum pump 84 is configured to achieve UHV in the specimen chamber 52. For example, the internal vacuum pump 84 has a gross pumping capacity of at least 30l/s, or more specifically 30 l/s to 5,000 l/s. In some implementations, the internal vacuum pump 84 has a gross pumping capacity of at least 50 l/s. In some implementations, the internal vacuum pump 84 has a gross pumping capacity of at least 100 l/s. In some implementations, the internal vacuum pump 84 has a gross pumping capacity of at least at least 500 l/s. In some implementations, the internal vacuum pump 84 has a gross pumping capacity of at least at least 1,000 l/s. In some implementations, the internal vacuum pump 84 has a gross pumping capacity of at least at least 1,600 l/s. As an example, factoring for restrictions that occur from within the specimen chamber 52 itself (e.g., due to the limited space between and around the NEG units 86), the total (net) internal pumping capacity is modeled to be greater than 1,000l/s when employing NEGs having a gross capacity of 1,600 l/s. This represents an increase in the effective pumping speed Sₑ that otherwise cannot be achieved. However, depending on the size, conditions, and restrictions in the particular specimen chamber, other pumping capacities (higher or lower, e.g., as described above) may be suitable to achieve UHV (or other desired vacuum pressures) in other implementations.

In operation, the microscope M is initially set up once to achieve UHV in the specimen chamber using the NEGs (though in some implementations it may still be desirable to achieve near UHV, or any other desired vacuum pressure that is lower than typically achieved by pumping through the pumping port 82). Thereafter, the NEGs continue to maintain the desired vacuum pressure in the microscope M and may be reactivated after column vents to maintain/restore the desired vacuum pressure.

The initial setup (see method 100 in FIG. 4) for initially achieving UHV (or other desired vacuum pressure) in the specimen chamber 52 includes: providing the specimen chamber 52 (e.g., configured to receive the specimen holder H in the imaging position intersecting the optical axis B′) (see step 101), activating the external vacuum pump 70 to create an initial vacuum condition in the specimen chamber 52 (see step 103), and activating the NEG(s) to further lower a pressure in the specimen chamber 52 (see step 104). Step 101 may further include disposing the NEG(s) in the specimen chamber 52. Step 101 may further include providing a magnetic assembly 50, or magnetic yoke 59, configured to provide a magnetic condition at the imaging position of the specimen holder H, and disposing the NEG(s) in the magnetic assembly 50. Step 101 may further include enlarging the specimen chamber volume 66 to accommodate the NEG(s).

More specifically (and with reference to FIG. 4), the initial setup (see method 100) for initially achieving the desired vacuum pressure in the specimen chamber 52 may further include baking the specimen chamber 52 at step 102 (after step 101) and pumping (e.g., pumping during baking) to create the initial vacuum condition at step 103. The initial vacuum condition may, for example, include a pressure in the range of 10\hat{ }-7 millibars to 10\hat{ }-9 millibars, or more specifically from 10\hat{ }-8 millibars to 10\hat{ }-9 millibars. However, in some implementations, the initial vacuum condition may be 10\hat{ }-7 millibars to 10\hat{ }-8 millibars. For example, the specimen chamber 52 may be baked to a temperature of 120 degrees Celsius or greater, and the external vacuum pump 70 may be employed to pump at step 103 to move fluid through the pumping port 82. Baking helps remove/evaporate molecules from the walls 68 defining the specimen chamber 52, thereby reducing the propensity for off-gassing after the initial setup. In some implementations, baking may be optional. The external pump may be stopped after the initial vacuum condition is achieved.

At step 104, the method 100 includes activating the NEG(s) to further lower the pressure in the specimen chamber 52. For example, activating may include heating the NEG(s) to their activation temperature (e.g., 400 degrees Celsius or any other suitable activation temperature for the sorption pump employed). The NEG(s) may be configured to achieve UHV, near UHV, or any other pressure that is better than typically achieved by pumping through the pumping port 82. For example, UHV may include a pressure of 10\hat{ }-10 millibars or better; near UHV may include a pressure of 10\hat{ }-9 millibars to 10\hat{ }-10 millibars; and any pressure lower than 10\hat{ }-8 millibars may also be desirable. Heating may be achieved using the heater(s) 88, which is activated electrically by way of the passthrough 90, e.g., by passing an electrical current from the external power source 94, through the electrical port 92 in the magnetic assembly 50, and to the heater 88. Step 104 may be performed after steps 101-103; however, in some implementations, it may be possible to perform step 101 and then step 104 without step 102 and/or without step 103.

The method 100 further includes cooling the NEG(s) (and the rest of the microscope M) to room temperature (e.g., 13 degrees Celsius) at step 105. Cooling may include passively allowing the microscope M to cool by radiation of heat to the external environment, or actively cooling the microscope M. Step 105 occurs after step 104. After step 105, the microscope M is ready to be used for imaging. However, steps 104-105 may be repeated, as desired, to maintain or reestablish the desired vacuum pressure. For example, steps 104-105 may be repeated after the specimen chamber of the microscope M is vented.

Thus, the disclosure provides, among other things, a charged particle microscope M having a low vacuum, which may be an ultra-high vacuum or other low vacuum, in the specimen chamber 52. Various features and advantages of the disclosure are set forth in the following claims.

What is claimed is:

1. A charged particle microscope for imaging a specimen, the charged particle microscope comprising:
a specimen holder movable into an imaging position intersecting an optical axis;
a specimen chamber configured to receive the specimen holder in the imaging position; and
a sorption pump disposed in the specimen chamber and configured to lower a pressure in the specimen chamber.

2. The charged particle microscope of claim 1, wherein the sorption pump is configured to achieve a pressure of 10\hat{ }-8 millibars or lower in the specimen chamber.

3. The charged particle microscope of claim 1, further comprising a magnetic yoke configured to concentrate magnetic field lines to guide a charged particle beam along the optical axis in the specimen chamber.

4. The charged particle microscope of claim 3, further comprising at least one coil for generating the magnetic field lines, wherein the magnetic yoke includes a yoke housing and at least one pole piece configured to create lens action.

5. The charged particle microscope of claim 3, wherein the sorption pump includes a non-evaporative getter, wherein the magnetic yoke defines an electrical port therein, the charged particle microscope further comprising:
an electrical feedthrough configured to pass through the electrical port, and
a heater disposed in the specimen chamber and configured to activate the non-evaporative getter, wherein the electrical feedthrough is configured to provide power to the heater.

6. The charged particle microscope of claim 3, the magnetic yoke including a yoke housing defining:
at least one pumping port configured to fluidly couple the specimen chamber to an external pump for lowering the pressure in the specimen chamber, and
a specimen port configured for inserting and removing the specimen holder with respect to the specimen chamber.

7. The charged particle microscope of claim 1, wherein an inner magnetic yoke height is defined in a direction parallel to the optical axis, the inner magnetic yoke height being at least 8 centimeters.

8. The charged particle microscope of claim 3, wherein the sorption pump is disposed within a volume defined by outermost magnetic field lines of the concentrated magnetic field lines, and wherein the sorption pump is relative non-magnetic.

9. A magnetic assembly for a charged particle microscope defining an optical axis, the magnetic assembly comprising:
at least one magnetic yoke configured to concentrate magnetic field lines for guiding a charged particle beam along the optical axis, the magnetic yoke at least partially defining a specimen chamber, the magnetic yoke defining at least one pumping port configured to fluidly couple the specimen chamber to an external pump for lowering a pressure in the specimen chamber; and
a sorption pump disposed in the specimen chamber and configured to further lower the pressure in the specimen chamber.

10. The magnetic assembly of claim 9, wherein the magnetic yoke further defines a specimen port configured to provide passage for a specimen holder into and out of the specimen chamber.

11. The magnetic assembly of claim 9, wherein the sorption pump is configured to achieve a pressure of 10\hat{ }-8 millibars or lower in the specimen chamber.

12. The magnetic assembly of claim 9, wherein the sorption pump is disposed in a volume defined by the concentrated magnetic field lines, and wherein the sorption pump is relatively non-magnetic.

13. The magnetic assembly of claim 9, wherein the sorption pump is disposed in a volume defined by the concentrated magnetic field lines.

14. The magnetic assembly of claim 13, wherein the magnetic yoke defines an inner magnetic yoke height defined in a direction parallel to the optical axis of at least 8 centimeters.

15. The magnetic assembly of claim 9, wherein the sorption pump includes a non-evaporative getter, and wherein the magnetic yoke further defines an electrical port therein, the magnetic assembly further comprising:
an electrical feedthrough configured to pass through the electrical port, and
a heater disposed in the specimen chamber and configured to activate the non-evaporative getter, wherein the electrical feedthrough is configured to provide power to the heater.

16. A method of achieving a vacuum in a charged particle microscope specimen chamber, the method comprising:
providing the specimen chamber configured to receive a specimen holder in an imaging position intersecting a charged particle optical axis;
activating a vacuum pump external to the specimen chamber to create an initial vacuum condition in the specimen chamber; and
activating a sorption pump disposed in the specimen chamber to further lower a pressure in the specimen chamber.

17. The method of claim 16, wherein the sorption pump is activated when the initial vacuum condition in the specimen chamber is created, and wherein activating the sorption pump achieves a pressure of 10\hat{ }-8 millibars or lower in the specimen chamber.

18. The method of claim 16, wherein the sorption pump includes a non-evaporable getter, and wherein activating includes heating the non-evaporable getter to an activation temperature.

19. The method of claim 16, wherein the charged particle microscope is a transmission electron microscope.

20. The method of claim 16, wherein the initial vacuum condition is in the range of 10\hat{ }-7 millibars to 10\hat{ }-9 millibars.
